(19) United States
(12) Patent Application Publication
(10) Pub. No.: US 2023/0089397 A1
(43) Pub. Date: Mar. 23, 2023

(54) AIR GAP FORMING METHOD AND SELECTIVE DEPOSITION METHOD

(71) Applicant: ASM IP Holding B.V., Almere (NL)

(72) Inventor: Seungju Chun, Hwaseong-si (KR)

(21) Appl. No.: 17/942,318

(22) Filed: Sep. 12, 2022

Related U.S. Application Data
(60) Provisional application No. 63/244,481, filed on Sep. 15, 2021.

(51) Int. Cl. H01L 21/768; C23C 16/44; C23C 16/455; H01L 21/02; C23C 14/48

(52) U.S. Cl. CPC H01L 21/7682; C23C 16/4408; C23C 16/45536; H01L 21/02131; C23C 14/48; H01L 21/0228

(57) ABSTRACT

An air gap forming method of forming an air gap in a gap structure having an upper surface, a lower surface, and a sidewall connecting the upper and lower surface, includes: repeatedly performing a selective deposition cycle, wherein the selective deposition cycle includes supplying a deposition inhibitor onto a substrate including the gap structure; and selectively forming a material layer on the upper surface compared to the sidewall.

### CROSS-REFERENCE TO RELATED APPLICATIONS

This application claims priority to U.S. Provisional Patent Application Ser. No. 63/244,481, filed Sep. 15, 2021, and titled AIR GAP FORMING METHOD AND SELECTIVE DEPOSITION METHOD, the disclosure of which is hereby incorporated by reference in its entirety.

### BACKGROUND

### 1. Field

One or more embodiments relate to an air gap forming method and a selective deposition method, and more particularly, to an air gap forming method and a selective deposition method that can be easily applied to form a gap structure and control the shape and size of an air gap.

### 2. Description of the Related Art

In the manufacture of a dynamic random access memory (DRAM) semiconductor device, degradation of device performance occurs, for example, RC delay or reaction speed, due to the parasitic capacitance generated between cells as cell spacing shrinks due to process miniaturization. As a solution to this problem, using an insulator with a low dielectric constant and an air gap has been considered. There is a need for a method capable of manufacturing an air gap in a more suitable size and shape.

### SUMMARY

One or more embodiments include an air gap forming method capable of being easily applied to form a gap structure and control the shape and size of an air gap.

One or more embodiments include a selective deposition method.

Additional aspects will be set forth in part in the description which follows and, in part, will be apparent from the description, or may be learned by practice of the presented embodiments of the disclosure.

According to one or more embodiments, an air gap forming method of forming an air gap in a gap structure having an upper surface, a lower surface, and a sidewall connecting the upper and lower surfaces, the air gap forming method includes: repeatedly performing a selective deposition cycle, wherein the selective deposition cycle includes: supplying a deposition inhibitor onto a substrate including the gap structure; and selectively forming a material layer on the upper surface compared to the sidewall.

In some embodiments, the supplying of the deposition inhibitor includes performing a first sub-cycle once or a plurality of times, wherein the first sub-cycle may include: supplying an ionized deposition inhibitor onto the substrate; and supplying a purge gas. In some embodiments, the selectively forming of the material layer includes performing a second sub-cycle once or a plurality of times, wherein the second sub-cycle may include: supplying a source material; purging an excess of a source material; supplying an ionized first reactant; and purging an excess of a first reactant.

In some embodiments, the air gap forming method may further include performing one or a plurality of ion bombardment sub-cycles between the supplying of the deposition inhibitor and the selectively forming of the material layer. The ion bombardment sub-cycle may include: supplying a second reactant onto the substrate; supplying plasma to a reaction space by ionizing and impinging the second reactant substantially perpendicularly onto the substrate; and purging an excess of a second reactant.

In some embodiments, a ratio of the number of times of performing the first sub-cycle to the number of times of performing the second sub-cycle may be 1:1 to 1:40. In some embodiments, a ratio of the number of times of performing the first sub-cycle to the number of times of performing the second sub-cycle may be 1:20 to 1:30.

In some embodiments, the deposition inhibitor may be a halogen-containing compound. In some embodiments, the halogen-containing compound may be at least one selected from a group consisting of F₂, SF₆, CF₄, C₂F₆, CHF₃, CH₂F₂, ClF₃, NF₃, C₃F₈, C₄F₈, HF, SiF₄, Cl₂, HCl, BCl₃, CCl₄, SiCl₄, SiHCl₃, SiH₂Cl₂, Si₂Cl₆, CHCl₃, CH₂Cl₂, CH₃Cl, PCl₃, PCl₅, POCl₃, NCl₃, S₂Cl₂, SOCl₂, SO₂Cl₂, COCl₂, and HBr.

In some embodiments, by the supplying of the deposition inhibitor, a layer of a halogen element may be uniformly formed on the upper surface, the lower surface, and the sidewall of the gap structure. In some embodiments, as the second sub-cycle is repeated while the selectively forming of the material layer is performed, the layer of the halogen element on the upper surface may be removed faster than the layer of the halogen element on the sidewall is removed.

According to one or more embodiments, a selective deposition method of selectively depositing a material layer on a gap structure having an upper surface, a lower surface, and a sidewall connecting the upper surface and the lower surface, the selective deposition method includes repeating selective deposition cycles within a reaction chamber. The selective deposition cycle may include: forming a deposition inhibiting layer on the upper surface, the lower surface, and the sidewall; selectively removing the deposition inhibiting layer from the upper surface relative to the sidewall; and selectively depositing the material layer on the upper surface while the deposition inhibiting layer remains on the sidewall.

In some embodiments, the selectively removing of the deposition inhibiting layer from the upper surface and the selectively depositing of the material layer on the upper surface may be performed simultaneously.

In some embodiments, the uniformly forming of the deposition inhibitory layer may include: ionizing a deposition inhibitor; and supplying the ionized deposition inhibitor onto the substrate. In some embodiments, the selectively depositing of the material layer on the upper surface may include: supplying a source material onto the substrate; and supplying an ionized first reactant on the substrate after the supplying of the source material.

In some embodiments, the selectively removing of the deposition inhibiting layer from the upper surface may be performed prior to the selectively depositing of the material layer on the upper surface, wherein the selectively removing of the deposition inhibiting layer from the upper surface may include repeating one or more ion bombardment cycles including: supplying a second reactant onto the substrate; applying RF power to a reaction space by ionizing and impinging the second reactant substantially perpendicularly onto the substrate; and purging an excess of the second reactant.

In some embodiments, the first reactant and the second reactant may each independently include at least one selected from a group consisting of O₂, O₃, plasma O₂, plasma O₃, water vapor, plasma H₂O, NO, plasma NO, N₂O, plasma N₂O, NO₂, plasma NO₂, hydrogen peroxide, CO, plasma CO, CO₂, plasma CO₂, nitrogen (N₂), ammonia (NH₃)), hydrazine (N₂H₄), diazene (N₂H₂), plasma N₂, plasma NH₃, plasma H₂, and NF₃.

In some embodiments, the material layer is silicon oxide or silicon nitride, and the source material may be at least one selected from a group consisting of silane (SiH₄), disilane (Si₂H₆), trisilane (Si₃H₈), monochlorosilane (SiClH₃), dichlorosilane (SiCl₂H₂, DCS), trichlorosilane (SiCl₃H), tetrachlorosilane (SiCl₄), hexachlorodisilane (Si₂Cl₆, HCD), diiodosilane (SiH₂I₂, DIS), triiodosilane (Sil₃H, TIS), diethylsilane (Et₂SiH₂), tetraethyl orthosilicate (Si(OCH₂CH₃)₄, TEOS), diisopropylaminosilane (H₃Si(N(i-Pr)₂)), bis(tertiary-butylamino)silane ((C₄H₉(H)N)₂SiH₂), tetrakis(ethylamino)silane (Si(NHEt)₄), tetrakis(dimethylamino)silane (Si(NMe₂)₄), tetrakis(ethylmethylamino)silane (Si(NEtMe)₄), tetrakis(diethylamino)silane (Si(NEt₂))₄), tris(dimethylamino)silane (HSi(NMe₂)₃), tris(ethylmethylamino)silane (HSi(NEtMe)₃), tris(diethylamino)silane (HSi(NEt₂)₃), tris(dimethylhydrazino)silane (HSi(N(H)NMe₂)₃), bis(diethylamino)silane (H₂Si(NEt₂)₂), bis(diisopropylamino)silane (H₂Si(N(i-Pr)₂)₂), tris(isopropylamino)silane (HSi(N(i-Pr)₂)₃), (diisopropylamino)silane (H₃SiN(i-Pr)₂), trisilylamine ((SiH₃)₃N, TSA), disiloxane (DSO), disilylmethylamine ((SiH₃)₂NMe, DSMA), disilylethylamine ((SiH₃)₂NEt, DSEA), disilylisopropylamine ((SiH₃)₂N(i-Pr), DSIPA), disilyl-tert-butylamine ((SiH₃)₂N(tBu), DSTBA), diethylsilylamine (SiH₃NEt₂, DESA), di-tert-butylsilylamine (SiH₃N(tBu)₂, DTBSA), bis(diethylamino)silane (SiH₂(NEt₂)₂, BDEAS), bis(dimethylamino)silane (SiH₂(NMe₂)₂, BDMAS), bis(ethylmethylamino)silane (SiH₂[N(Et)(Me)]₂, BEMAS), bis(tert-butylamino)silane (SiH₂(NHtBu)₂, BTBAS), diisopropylsilylamine (SiH₃N(i-Pr)₂, DIPSA), hexakis(ethylamino)disilane (Si₂(NHEt)₆), and bis(trimethylsilylamino)silane (SiH₂(NHSiMe₃)₂, BITS).

In some embodiments, during the uniformly forming of the deposition inhibiting layer, high-frequency RF power and low-frequency RF power may be simultaneously supplied to the reaction chamber. In some embodiments, during the selectively removing of the deposition inhibiting layer from the upper surface relative to the sidewall, high-frequency RF power and low-frequency RF power may be simultaneously supplied to the reaction chamber. In some embodiments, a shape and a volume of the air gap may be substantially respectively the same as a shape and a volume of a gap space surrounded by sidewalls, a bottom surface, and an upper area of a gap.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart schematically illustrating a method of forming a material layer according to an embodiment;

FIGS. 2A to 2C are side cross-sectional views illustrating a method of forming a material layer according to an embodiment;

FIG. 3A is a detailed flowchart illustrating a method of forming a deposition inhibiting layer on an upper surface, a lower surface, and a sidewall;

FIG. 3B is a detailed flowchart illustrating a method of selectively forming a material layer on the upper surface, compared to the sidewall;

FIG. 4 is a timing diagram illustrating the methods of FIGS. 3A and 3B;

FIG. 5 is a schematic view illustrating a method of forming a material layer according to an embodiment;

FIG. 6 is a graph for comparing film formation rates of a material layer in the absence of a deposition inhibiting layer and in the presence of a deposition inhibiting layer;

FIGS. 7A to 7D are images illustrating a profile of a SiO₂ film formed on a gap structure according to each step of FIG. 6;

FIGS. 8A and 8B are images illustrating the formation of a SiO₂ material layer according to the number of deposition cycles in section B of FIG. 6;

FIG. 9 is a flowchart illustrating a method of forming a material layer according to another embodiment;

FIG. 10 is a detailed flowchart illustrating a method of selectively removing a deposition inhibiting layer from an upper surface of FIG. 9;

FIG. 11 is a timing diagram illustrating the method of FIG. 10; and

FIG. 12 is a view of a substrate processing apparatus to which a method of manufacturing a semiconductor device according to embodiments may be applied.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, one or more embodiments will be described more fully with reference to the accompanying drawings.

In this regard, the present embodiments may have different forms and should not be construed as being limited to the descriptions set forth herein. Rather, these embodiments are provided so that the disclosure will be thorough and complete, and will fully convey the scope of the disclosure to one of ordinary skill in the art.

The terminology used herein is for describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, processes, members, components, and/or groups thereof, but do not preclude the presence or addition of one or more other features, integers, steps, processes, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

In the specification, “gas” may include evaporated solids and/or liquids and may include a single gas or a mixture of gases. In the specification, a process gas introduced into a reaction chamber through a shower head may include a precursor gas and an additive gas. The precursor gas and the additive gas may typically be introduced as a mixed gas or may be separately introduced into a reaction space. The precursor gas may be introduced together with a carrier gas such as an inert gas. The additive gas may include a dilution gas such as a reactive gas and an inert gas. The reactive gas and the dilution gas may be mixedly or separately introduced into the reaction space. The precursor may include two or more precursors, and the reactive gas may include two or more reactive gases. The precursor may be a gas that is chemisorbed onto a substrate and typically contains metalloid or metal elements constituting a main structure of a matrix of a dielectric film, and the reactive gas for deposition may be a gas that is reactive with the precursor chemisorbed onto the substrate when excited to fix an atomic layer or a monolayer on the substrate. The term “chemisorption” may refer to chemical saturation adsorption. A gas other than the process gas, that is, a gas introduced without passing through the shower head, may be used to seal the reaction space, and it may include a seal gas such as an inert gas. In some embodiments, the term “film” may refer to a layer that extends continuously in a direction perpendicular to a thickness direction without substantially having pinholes to cover an entire target or a relevant surface, or may refer to a layer that simply covers a target or a relevant surface. In some embodiments, the term “layer” may refer to a structure, or a synonym of a film, or a non-film structure having any thickness formed on a surface. The film or layer may include a discrete single film or layer or multiple films or layers having some characteristics, and the boundary between adjacent films or layers may be clear or unclear and may be set based on physical, chemical, and/or some other characteristics, formation processes or sequences, and/or functions or purposes of the adjacent films or layers.

In the specification, the expression “containing an Si—N bond” may be referred to as characterized by an Si—N bond or Si—N bonds having a main skeleton substantially constituted by the Si—N bond or Si—N bonds and/or having a substituent substantially constituted by the Si-N bond or Si—N bonds. A silicon nitride layer may be a dielectric layer containing a Si—N bond, and may include a silicon nitride layer (SiN) and a silicon oxynitride layer (SiON).

In the specification, the expression “same material” should be interpreted as meaning that main components (constituents) are the same. For example, when a first layer and a second layer are both silicon nitride layers and are formed of the same material, the first layer may be selected from the group consisting of Si₂N, SiN, Si₃N₄, and Si₂N₃ and the second layer may also be selected from the above group but a particular film quality thereof may be different from that of the first layer.

In addition, in the specification, according as an operable range may be determined based on a regular job, any two variables may constitute an operable range of the variable and any indicated range may include or exclude terminated sites. Additionally, the values of any indicated variables may refer to exact values or approximate values (regardless of whether they are indicated as “about”), may include equivalents, and may refer to an average value, a median value, a representative value, a majority value, or the like.

In the specification where conditions and/or structures are not specified, one of ordinary skill in the art may easily provide these conditions and/or structures as a matter of customary experiment in the light of the specification. In all described embodiments, any component used in an embodiment may be replaced with any equivalent component thereof, including those explicitly, necessarily, or essentially described herein, for intended purposes, and in addition, the disclosure may be similarly applied to devices and methods.

Hereinafter, embodiments of the disclosure will be described with reference to the accompanying drawings. In the drawings, variations from the illustrated shapes may be expected because of, for example, manufacturing techniques and/or tolerances. Thus, the embodiments of the disclosure should not be construed as being limited to the particular shapes of regions illustrated herein but may include deviations in shapes that result, for example, from manufacturing processes.

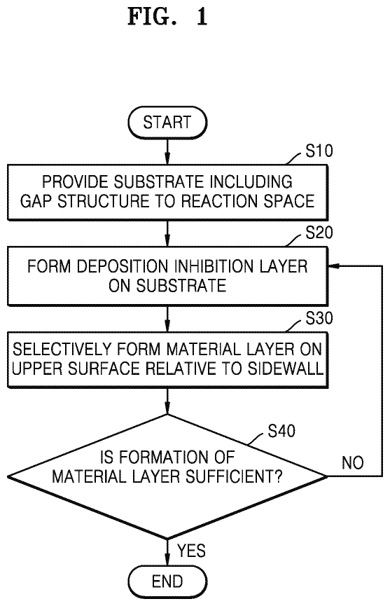

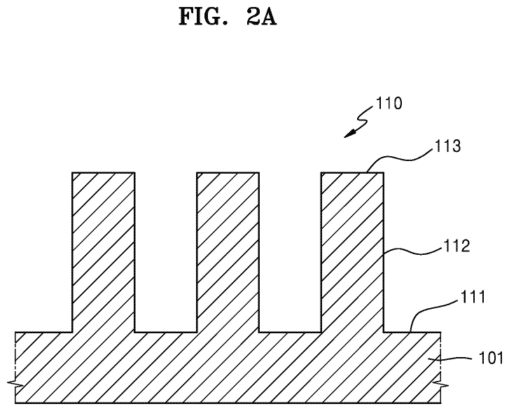

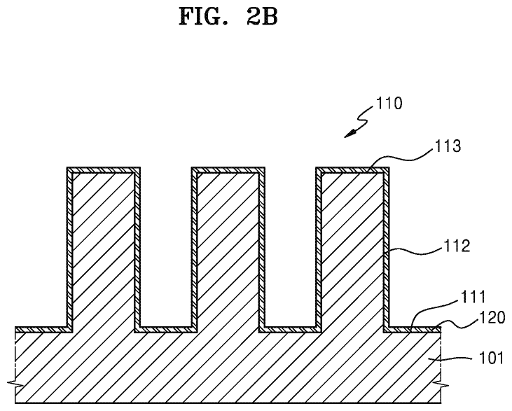

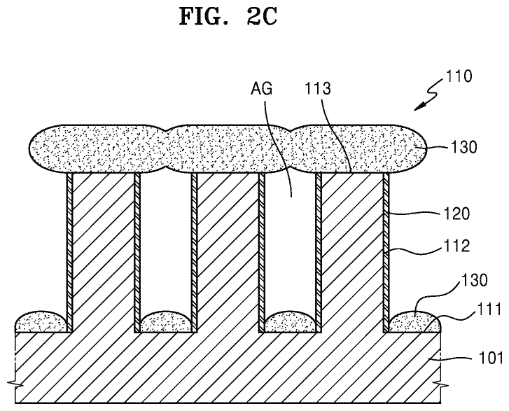

FIG. 1 is a flowchart schematically illustrating a method of forming a material layer according to an embodiment. FIGS. 2A to 2C are side cross-sectional views illustrating a method of forming a material layer according to an embodiment.

Referring to FIGS. 1 and 2A, in operation S10, a substrate including a gap structure 110 is provided to a reaction space.

The gap structure 110 of the substrate includes an upper surface 113, a lower surface 111, and a sidewall 112 connecting the upper surface 113 to the lower surface 111. The topography forming the upper surface 113 and the sidewall 112 of the gap structure 110 may be a separate structure formed on a base substrate 101 having the lower surface 111, or may be integrated with the base substrate 101.

The sidewall 112 may extend generally perpendicular or at an angle with respect to the lower surface 111.

Referring to FIGS. 1 and 2B, in operation S20, a deposition inhibitor may be supplied on the substrate, and a deposition inhibiting layer 120 may be formed on the upper surface 113, the lower surface 111, and the sidewall 112. In some embodiments, the deposition inhibiting layer 120 may be formed to have a substantially uniform thickness.

The deposition inhibiting layer 120 is a material layer removable by ion bombardment, and may inhibit deposition of another material layer thereon which may be formed by an atomic layer deposition (ALD) method. In addition, as a deposition cycle is repeated, the deposition inhibiting layer 120 may be gradually removed. Accordingly, as the deposition cycle is repeated, the deposition is inhibited until a certain number of deposition cycles are repeated, but deposition may be allowed thereafter.

In addition, because ions move in a vertical direction when the deposition of the ALD method is performed by a plasma enhanced ALD method, a horizontal plane of a gap structure, that is, a deposition inhibiting layer on a surface of the gap structure that is perpendicular to an ion propagation direction is removed faster than a deposition inhibiting layer on a vertical surface of the gap structure, that is, on a surface of the gap structure that is horizontal or oblique to the ion propagation direction, thereby increasing the deposition rate. The deposition inhibiting layer 120 may be formed by performing a first sub-cycle, which will be described in detail later below, once or a plurality of times.

Referring to FIGS. 1 and 2C, in operation S30, a material layer 130 is selectively formed on the upper surface 113 compared to the sidewall 112.

The material layer 130 may be formed by a plasma enhanced ALD (PEALD) method. A non-removed deposition inhibiting layer 120 may remain on the sidewall 112. The material layer 130 may be selectively formed on the upper surface 113 due to the deposition inhibiting layer 120 remaining on the sidewall 112.

In addition, in the material layer 130 formed on the upper surface 113, an air gap AG may be formed between two sidewalls 112 that are connected to each other and face each other. In some embodiments, the material layer 130 may also be partially formed on the lower surface 111.

Although FIG. 2C illustrates an example in which the material layer 130 is not formed on the sidewall 112 at all, in some other embodiments, a material layer on the sidewall 112 may be formed relatively thinly, discontinuously, or locally as compared to a material layer on the upper surface 113.

The material layer 130 may be formed by performing a second sub-cycle, which will be described in detail later below, a plurality of times.

Thereafter, in operation S40, it is determined whether the formation of the material layer 130 is sufficient. When the formation of the material layer 130 is sufficient, the material layer formation process is stopped. When the formation of the material layer 130 is insufficient, operation S20 of forming a deposition inhibiting layer and operation S30 of selectively forming a material layer on an upper surface may be performed one or more times.

Operation S20 of forming the deposition inhibiting layer and operation S30 of selectively forming a material layer on the upper surface may achieve a grand-cycle for forming the material layer. That is, the grand-cycle may be performed once or a plurality of times.

FIG. 2C shows that material layers 130 formed on two adjacent upper surfaces 113 are connected to each other to form the air gap AG, but the material layers 130 are not necessarily connected to each other. Accordingly, the material layer may be independently and selectively formed on the upper surfaces 113.

Hereinafter, the method of forming the material layer will be described in more detail.

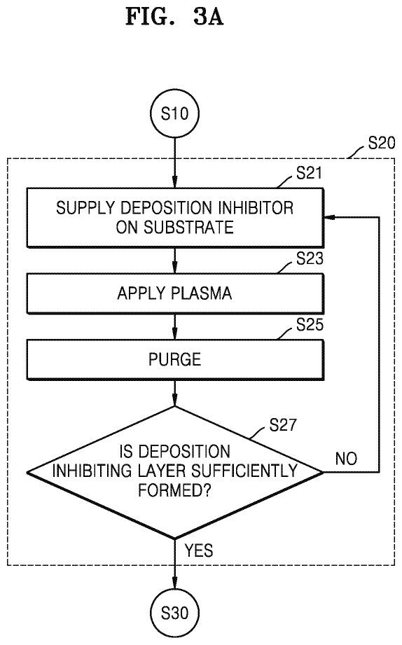

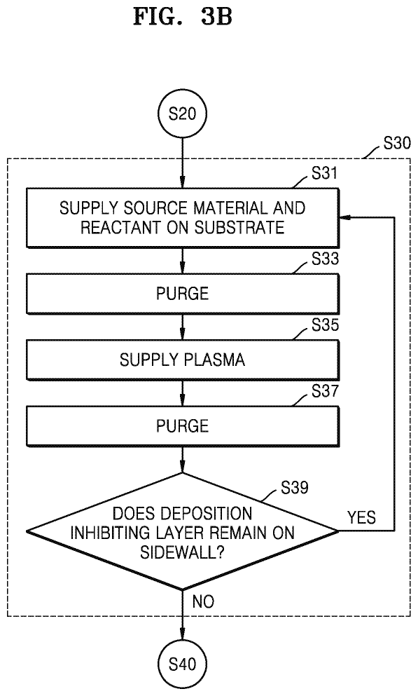

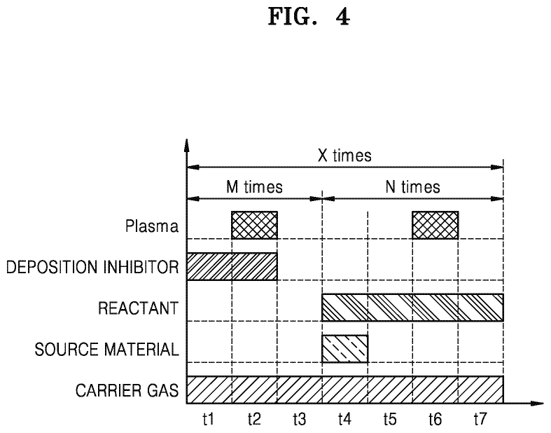

FIG. 3A is a detailed flowchart illustrating a method of forming the deposition inhibiting layer 120 on the upper surface 113, the lower surface 111, and the sidewall 112. FIG. 3B is a detailed flowchart illustrating a method of selectively forming the material layer 130 on the upper surface 113 compared to the sidewall 112. FIG. 4 is a timing diagram illustrating the methods of FIGS. 3A and 3B.

First Period (t1)

Referring to FIGS. 2B, 3A, and 4, in operation S21, in order to form the deposition inhibiting layer 120 on a substrate including the upper surface 113, the lower surface 111 and the sidewalls 112, a deposition inhibitor is first supplied on the substrate during the first period (t1).

The deposition inhibitor may be, for example, a halogen-containing compound, such as a compound containing fluorine (F), chlorine (Cl), bromine (Br), iodine (I), or the like.

In some embodiments, the halogen-containing compound may be at least one selected from a group consisting of F₂, SF₆, CF₄, C₂F₆, CHF₃, CH₂F₂, ClF₃, N F₃, C₃F₈, C₄F₈, HF, SiF₄, Cl₂, HCl, BCl₃, CCl₄, SiCl₄, SiHCl₃, SiH₂Cl₂, Si₂Cl₆, CHCl₃, CH₂Cl₂, CH₃Cl, PCl₃, PCl₅, POCl₃, NCl₃, S₂Cl₂, SOCl₂, SO₂Cl₂, COCl₂, and HBr.

A flow rate for supplying the deposition inhibitor may be about 5 sccm to about 300 sccm. When the flow rate for supplying the deposition inhibitor is too small, it may take too long to form a deposition inhibiting layer. When the flow rate for supplying the deposition inhibitor is too large, a growth rate of the deposition inhibition layer is saturated and the deposition inhibitor is unnecessarily consumed, which may be economically disadvantageous. In addition, because the deposition inhibiting layer is excessively formed, it may be difficult to deposit a material layer in a subsequent deposition step.

The deposition inhibitor may be carried by a carrier gas. The carrier gas is an inert gas, and Ar, He, N₂, Ne, etc. may be used, but is not limited thereto. A flow rate of the carrier gas may be appropriately selected considering factors such as a deposition rate of a deposition inhibiting layer, a vapor pressure of a deposition inhibitor to be transported, and the temperature. For example, about 1000 sccm to about 3000 sccm of Ar or nitrogen (N₂) gas may be supplied as a carrier gas. The carrier gas serves to transport a source material, a reactant material, and a deposition inhibitor during a substrate processing process, but may also serve as a purge gas to remove a residual gas in a reactor.

In addition, in order to prevent a process gas, such as a source material, a deposition inhibitor, and a reactant, from penetrating into a lower portion of a susceptor supporting a substrate in a reaction space, a filling gas may be further provided to the lower portion of the susceptor. The filling gas may be, for example, nitrogen (N₂), and may be provided at a flow rate of about 50 sccm to about 200 sccm.

Second Period (t2)

Thereafter, in operation S23, the deposition inhibitor may be activated by supplying plasma to a reaction space in which the substrate is mounted. The plasma may be generated by supplying RF power to a reactor. That is, plasma may be applied while continuously supplying the deposition inhibitor on the substrate during the second period (t2).

The activated deposition inhibitor may leave a layer of ionized halogen element on the upper surface 113, the lower surface 111, and the sidewall 112, which may form a deposition inhibition layer or a portion thereof. In more detail, because of applying the plasma, a layer of F, Cl, Br, I, etc. may be formed on the upper surface 113, the lower surface 111, and the sidewall 112.

A time for applying the plasma (i.e., the duration of the second period (t2)) may be about 0.1 second to about 1 second. At this time, in order to apply the plasma, dual frequency RF power, that is, high-frequency RF power and low-frequency RF power, may be simultaneously supplied to the reaction space.

In some embodiments, the high-frequency RF power may have a frequency of about 13.56 MHz, and may be supplied with power of about 100 W to about 400 W. In some embodiments, the low-frequency RF power may have a frequency of about 400 kHz, and may be supplied with power of about 50W to about 150W. For example, high-frequency RF power of 13.56 MHz increases an ionization rate of a deposition inhibitor and increases the density of active fluorine species. In addition, low-frequency RF power of 400 kHz may form fluorine-terminated sites uniformly up to side and bottom surfaces of a gap by increasing a movement distance of the active fluorine species.

A layer of a halogen element may be generated on the upper surface 113, the lower surface 111, and the sidewall 112 while the deposition inhibitor is activated and decomposed by the supply of the RF power and the application of the plasma.

Third period (t3)

Thereafter, in operation S25, the reaction space may be purged. The application of the plasma may be stopped to purge the reaction space.

In some embodiments, the purge operation may be performed by continuously flowing a carrier gas used in the plasma application operation (S23) described above for the third period (t3). As a flow rate of the carrier gas, for example, about 1000 sccm to about 6000 sccm of Ar or N₂ gas may be supplied. In the purge step, a residual gas remaining in a reactor may be removed. For example, reaction by-products decomposed by plasma, elements not adsorbed to a gap structure, etc. may be removed.

The time the purge operation is performed (i.e., the duration of the third period (t3)) may be about 0.1 second to about 1 second.

The above operations S21, S23, and S25 may form a first sub-cycle. That is, the first period (t1), the second period (t2) and the third period (t3) in FIG. 4.

Thereafter, in operation S27, it is determined whether the deposition inhibiting layer 120 is sufficiently formed. When the formation of the deposition inhibiting layer 120 is insufficient, the first sub-cycle may be repeatedly performed until the deposition inhibiting layer 120 is sufficiently formed. In some embodiments, the first sub-cycle may be performed once within one grand-cycle (M=1). In some other embodiments, the first sub-cycle may be performed 2 to 10 times consecutively within one grand-cycle (M=2 to 10).

When the formation of the deposition inhibiting layer 120 is sufficient, the next operation, that is, operation S30 of selectively forming a material layer on an upper surface compared to a sidewall is performed.

Fourth Period (t4)

Referring to FIGS. 2B, 3B, and 4, in operation S31, a source material and a reactant are supplied on the substrate including the upper surface 113, the lower surface 111, and the sidewalls 112 during the fourth period (t4).

The source material and the reactant may be selected according to a type of a material layer to be formed on the substrate.

In some embodiments, the material layer may be a silicon oxide layer, the source material may be a silicon precursor containing silicon, and the reactant may be an oxidizing agent containing oxygen. In some other embodiments, the material layer may be a silicon nitride layer, the source material may be a silicon precursor containing silicon, and the reactant may be a compound containing nitrogen.

In more detail, the silicon precursor may be, for example, at least one selected from a group consisting of silane (SiH₄), disilane (Si₂H₆), trisilane (Si₃H₈), monochlorosilane (SiClH₃), dichlorosilane (SiCl₂H₂, DCS), trichlorosilane (SiCl₃H), tetrachlorosilane (SiCl₄), hexachlorodisilane (Si₂Cl₆, HCD), diiodosilane (SiH₂I₂, DIS), triiodosilane (Sil₃H, TIS), diethylsilane (Et₂SiH₂), tetraethyl orthosilicate (Si(OCH₂CH₃)₄, TEOS), diisopropylaminosilane (H₃Si(N(i-Pr)₂)), bis(tertiary-butylamino)silane ((C₄H₉(H)N)₂SiH₂), tetrakis(ethylamino)silane (Si(NHEt)₄), tetrakis(dimethylamino)silane (Si(NMe₂)₄), tetrakis(ethylmethylamino)silane (Si(NEtMe)₄), tetrakis(diethylamino)silane (Si(NEt₂))₄), tris(dimethylamino)silane (HSi(NMe₂)₃), tris(ethylmethylamino)silane (HSi(NEtMe)₃), tris(diethylamino)silane (HSi(NEt₂)₃), tris(dimethylhydrazino)silane (HSi(N(H)NMe₂)₃), bis(diethylamino)silane (H₂Si(NEt₂)₂), bis(diisopropylamino)silane (H₂Si(N(i-Pr)₂)₂), tris(isopropylamino)silane (HSi(N(i-Pr)₂)₃), (diisopropylamino)silane (H₃SiN(i-Pr)₂), trisilylamine ((SiH₃)₃N, TSA), disiloxane (DSO), disilylmethylamine ((SiH₃)₂NMe, DSMA), disilylethylamine ((SiH₃)₂NEt, DSEA), disilylisopropylamine ((SiH₃)₂N(i-Pr), DSIPA), disilyl-tert-butylamine ((SiH₃)₂N(tBu), DSTBA), diethylsilylamine (SiH₃NEt₂, DESA), di-tert-butylsilylamine (SiH₃N(tBu)₂, DTBSA), bis(diethylamino)silane (SiH₂(NEt₂)₂, BDEAS), bis(dimethylamino)silane (SiH₂(NMe₂)₂, BDMAS), bis(ethylmethylamino)silane (SiH₂[N(Et)(Me)]₂, BEMAS), bis(tert-butylamino)silane (SiH₂(NHtBu)₂, BTBAS), diisopropylsilylamine (SiH₃N(i-Pr)₂, DIPSA), hexakis(ethylamino)disilane (Si₂(NHEt)₆), and bis(trimethylsilylamino)silane (SiH₂(NHSiMe₃)₂, BITS).

The reactant may be, for example, at least one selected from a group consisting of O₂, O₃, plasma O₂, plasma O₃, water vapor, plasma H₂O, NO, plasma NO, N₂O, plasma N₂O, NO₂, plasma NO₂, hydrogen peroxide, CO, plasma CO, CO₂, plasma CO₂, nitrogen (N₂), ammonia (NH₃)), hydrazine (N₂H₄), diazene (N₂H₂), plasma N₂, plasma NH₃, plasma H₂, and NF₃.

In some embodiments, the material layer may be zirconium oxide or zirconium nitride, and the source material may be a zirconium precursor. The zirconium precursor may be, for example, at least one selected from (cyclopentadienyl)tris(dimethylamino)zirconium (CpZr(NMe₂)₃), tetrakis-ethylmethylamido-zirconium (TEMAZ), tetrakis-diethylamido-zirconium (TDEAZ), tetrakis-dimethylamido-zirconium (TDMAZ), bis-diisopropylamido-bis-dimethylamido-zirconium, bis-di-t-butylamido-bis-dimethylamido-zirconium, bis-ethylmethylamido-bis-diisopropylamido-zirconium, bis-diethylamido-bis-diisopropylamido-zirconium, zirconium tertiary butoxide (Zr(OtBu)₄, ZTB), tetrakis(1-methoxy-2-methyl-2-propoxy)zirconium (Zr(mmp)₄), zirconium tetrachloride (ZrCl₄), ZrCp₂Me₂, Zr(tBuCp)₂Me₂, Zr(N(iPr)₂)₄, and tris-diethylamido-diisopropylamido-zirconium, but is not limited thereto.

In some embodiments, the material layer may be hafnium oxide or hafnium nitride, and the source material may be a hafnium precursor. The hafnium precursor may be, for example, at least one selected from hafnium tertiary butoxide (Hf(OtBu)₄, HTB), tetrakis(diethylamido)hafnium (Hf(NEt₂)₄, TDEAH), tetrakis(ethylmethylamido)hafnium (Hf(NEtMe)₄, TEMAH), and tetrakis(dimethylamido)hafnium (Hf(NMe₂)₄, TDMAH), but is not limited thereto.

In some embodiments, the material layer may be yttrium (Y) oxide or yttrium nitride, and the source material may be an yttrium precursor. The yttrium precursor may be, for example, at least one selected from a group consisting of Y(N(SiMe₃)₂)₃, Y(N(i-Pr)₂)₃, Y(N(tBu)SiMe₃)₃, Y(TMPD)₃, Cp₃Y, (MeCp)₃Y, and Y(O(i-Pr))₃, but is not limited thereto.

In some embodiments, the material layer may be titanium (Ti) oxide or titanium nitride, and the source material may be a titanium precursor. The titanium precursor may be, for example, at least one selected from a group consisting of titanium tetrakis(isopropoxide) (Ti(O-iPr)₄), titanium halide, cyclopentadienyl titanium, and titanium bis(isopropoxide)bis(2,2,6,6-tetramethyl-3,5-heptanedionate) (Ti(O-iPr)₂(thd)₂), tetrakisdimethylaminotitanium (Ti[N(CH₃)₂]₄, TDMAT), and tetrakis(diethylamino)titanium ((Et₂N)₄Ti, TEMAT), but is not limited thereto.

In some embodiments, the material layer may be tantalum (Ta) oxide or tantalum nitride, and the source material may be a tantalum precursor. The tantalum precursor may include, for example, a tantalum compound such as tantalum pentachloride (TaCl₅), tantalum pentafluoride (TaF₅), pentakisdimethylaminotantalum (Ta(N(CH₃)₂)₅, PDMAT), pentakisdiethylaminotantalum (PDEAT; Ta(NEt₂)₅), pentakis(methylethylamido)tantalum (PMEAT; Ta(NMeEt)₅), tert-butyliminotris(dimethylamino)tantalum (TBTDMT, tBuNTa(NMe₂)₃), tert-butyliminotris(diethylamino)tantalum (TBTDET, tBuNTa(Net₂)₃), tert-butyliminotris(methylethylamino)tantalum (TBTMET, tBuNTa(NMeEt)₃), ethylimido-tris(dimethylamido)tantalum ((EtN)Ta(NMe₂)₃), ethylimido-tris(diethylamido)tantalum ((EtN)Ta(NEt₂)₃), ethylimido-tris(ethylmethylamido)tantalum ((EtN)Ta[N(Et)Me]₃), tert-amylimido-tris(dimethylamido)tantalum ((tAmylN)Ta(NMe₂)₃, where tAmyl is a tert-amyl group (CH₃CH₂C(CH₃)₂-)), tert-amyimido-tris(diethylamido)tantalum ((tAmylN)Ta(NEt₂)₃), tert-amylimido-tris(ethylmethylamido)tantalum ((tAmylN)Ta([N(Et)Me]₃), or derivatives thereof. However, the disclosure is not limited thereto.

In some embodiments, the material layer may be tungsten (W) oxide or tungsten nitride, and the source material may be a tungsten precursor. The tungsten precursor may include, for example, a tungsten compound such as bis(tertbutylimido)bis(tertiarybutylamido)tungsten ((tBuN)₂W(N(H)tBu)₂), bis(tertiarybutylimido)bis(dimethylamido)tungsten ((tBuN))₂W(NMe₂)₂), bis(tertbutylimido)bis(diethylamido)tungsten ((tBuN)₂W(NEt₂)₂), bis(tertiarybutylimido)bis(ethylmethylamido)tungsten ((tBuN)₂W(NEtMe)₂), tungsten hexafluoride, tungsten hexachloride, or derivatives thereof. However, the disclosure is not limited thereto.

In some embodiments, the material layer may be aluminum (Al) oxide or aluminum nitride, and the source material may be an aluminum precursor. The aluminum precursor may be, for example, at least one selected from a group consisting of trimethyl aluminum (TMA), triethyl aluminum (TEA), 1-methylpyrrolidine alane (MPA), dimethylethylamine alane (DMEAA), and dimethyl aluminum hydride (DMAH), but is not limited thereto.

In some embodiments, the material layer may be germanium (Ge) oxide or germanium nitride, and the source material may be a germanium precursor. The germanium precursor may be, for example, at least one selected from a group consisting of germane (GeH₄), digermane (Ge₂H₆), trigermane (Ge₃H₈), GeCl₄, Ge(Me)₄, and Ge(Et)₄, but is not limited thereto.

In some embodiments, the material layer may be boron (B) oxide or boron nitride, and the source material may be a boron precursor. The boron precursor may be, for example, at least one selected from a group consisting of borane (BH₃), diborane (B₂H₆), trifluoroborane (BF₃), trichloroborane (BCl₃), tribromoborane (BBr₃), and triiodoborane (Bl₃), but is not limited thereto.

Me is a methyl group, Et is an ethyl group, i-Pr is an isopropyl group, Bu is a butyl group, n-Bu is an n-butyl group, Cp is a cyclopentadienyl group, thd is 2,2,6,6-tetramethyl-3,5-heptanedionate, and TMPD is 2,2,6,6-tetramethyl-p-phenylenediamine.

In some embodiments, a flow rate for supplying the source material may be about 100 sccm to about 3000 sccm, and a flow rate for supplying the reactant may be about 500 sccm to about 2000 sccm.

When the flow rate for supplying the source material is too small, it may take too long to form a material layer having a desired thickness. When the flow rate for supplying the source material is too large, the source material may be consumed unnecessarily, which may be economically disadvantageous, and a purge time in a subsequent purge step may be long, resulting in a long substrate processing time. In other words, the source material is self-limiting chemisorbed on a surface of the substrate. When the flow rate of the supplied source material is too large, too much excess source material is not chemisorbed.

In another embodiment, the source material may be carried by a carrier gas. The carrier gas is an inert gas, and Ar, He, N₂, Ne, etc. may be used, but is not limited thereto. A flow rate of the carrier gas may be appropriately selected considering factors such as a flow rate of the source material, a vapor pressure of a source material to be transported, and the temperature. For example, about 1000 sccm to about 3000 sccm of Ar or N₂ gas may be supplied as a carrier gas.

In addition, in order to prevent a process gas, such as a source material, a deposition inhibitor, and a reactant, from penetrating into a lower space of a susceptor supporting a substrate in a reaction space, a filling gas may be further provided to the lower space of the susceptor. The filling gas may be, for example, N₂ gas, and may be provided at a flow rate of about 50 sccm to about 1000 sccm.

In some embodiments, the duration of the fourth period (t4) in which the source material is supplied may be about 0.1 second to about 1 second.

When the source material is supplied, the source material may be chemically adsorbed to an adsorption site where the source material may be chemically adsorbed on the substrate including the upper surface 113, the lower surface 111, and the sidewall 112.

As described above, because a deposition inhibiting layer is formed on the upper surface 113, the lower surface 111, and the sidewall 112, at the beginning of a second sub-cycle for forming a material layer, chemisorption of a source material may be extremely limited. However, as the second sub-cycle for forming the material layer is repeated, the deposition inhibiting layer is gradually removed while the number of purges is increased, so that the extent to which a source material is adsorbed may gradually increase accordingly. As will be described in more detail later, because the deposition inhibiting layer on the upper surface 113 is removed faster than the deposition inhibiting layer on the sidewall 112, a source material may be better chemisorbed on the upper surface 113 than on the sidewall 112.

Fifth Period (t5)

Thereafter, in operation S33, the supply of the source material may be stopped and the reaction space may be purged.

In some embodiments, the purge operation may be performed by continuously flowing the carrier gas used in operation S31 of supplying the source material and the reactant described above during the fifth period (t5). As the flow rate of the carrier gas, for example, about 200 sccm to about 3000 sccm of Ar or N₂ gas may be supplied.

In addition, a filling gas may be continuously provided to the lower space of the susceptor at a flow rate of about 50 sccm to about 1000 sccm.

In some embodiments, the reactant may be continuously supplied while the purge operation is performed. The supply rate of the reactant may be the same as that of the fourth period (t4).

The time the purge operation is performed (i.e., the duration of the fifth period (t5)) may be about 0.1 second to about 1 second.

Sixth Period (t6)

Thereafter, in operation S35, plasma may be applied to the reaction space in which the substrate is mounted to activate the reactant. That is, plasma may be applied while continuously supplying the reactant on the substrate during the sixth period (t6). The plasma may be generated by supplying RF power to the reaction space.

The activated reactant may react with a source material chemisorbed on the upper surface 113, the lower surface 111, and the sidewall 112 to form a material layer. The material layer may be oxide or nitride of a central element of the above-described source material.

As will be described in more detail later below, because chemisorption of a source material on the upper surface 113 is more active than in the sidewall 112 on which the deposition inhibiting layer 120 remains, the material layer may be formed on the upper surface 113 with higher selectivity.

In addition, because the reactant is ionized by plasma and has a vertical directionality, the deposition inhibiting layer remaining on the upper surface 113 is continuously removed by a reaction as shown in the following formula, which may enlarge a site where a source material can be chemisorbed at the fourth period (t4) of the next cycle.

2F⁻+(1/2)O₂+(ionization energy)→2F⁻+O²⁺→OF₂(↑)

In other words, selectively removing a deposition inhibiting layer and selectively depositing a material layer on an upper surface of a substrate may be performed substantially simultaneously.

A time for applying the plasma (i.e., the duration of the sixth period (t6)) may be about 0.1 second to about 1 second. At this time, in order to apply the plasma, high-frequency RF power having a frequency of about 13.56 MHz may be supplied to the reaction space at power of about 100 W to about 400 W. In some embodiments, unlike in the first sub-cycle, low-frequency RF power having a frequency of about 400 kHz may not be supplied.

The reactant may be carried by a carrier gas. The carrier gas is an inert gas, and Ar, He, N₂, Ne, etc. may be used, but is not limited thereto. A flow rate of the carrier gas may be appropriately selected considering factors such as a flow rate of the reactant, a vapor pressure of a reactant to be transported, and the temperature. For example, about 1000 sccm to about 3000 sccm of Ar or N₂ gas may be supplied as a carrier gas.

In addition, a filling gas may be continuously provided to a lower portion of the susceptor at a flow rate of about 50 sccm to about 1000 sccm.

In some embodiments, a reactant may be continuously supplied while the plasma application is performed. The supply rate of the reactant may be the same as that of the fourth period (t4).

Seventh Period (t7)

Thereafter, in operation S37, the application of the plasma may be stopped and the reaction space may be purged.

In some embodiments, the purge operation may be performed by supplying a carrier gas to the reaction space during the seventh period (t7). The carrier gas is an inert gas, and Ar, He, N₂, Ne, etc. may be used, but is not limited thereto. A flow rate of the carrier gas may be, for example, about 200 sccm to about 3000 sccm of Ar or N₂ gas.

In some embodiments, the reactant may be continuously supplied while the purge operation is performed. The supply rate of the reactant may be the same as that of the fourth period (t4).

The time the purge operation is performed (i.e., the duration of the seventh period (t7)) may be about 0.1 second to about 1 second.

The above operations S31, S33, S35, and S37 may constitute the second sub-cycle. That is, the fourth period (t4), the fifth period (t5), the sixth period (t6) and the seventh period (t7).

In operation S39, it is determined whether the deposition inhibiting layer 120 remains on the sidewall 112. When the deposition inhibiting layer 120 remains on the sidewall 112, the second sub-cycle may be repeated. In some embodiments, the second sub-cycle may be performed a plurality of times within the one grand-cycle.

A ratio of the number of times (M) that the first sub-cycle is performed and the number of times (N) that the second sub-cycle is performed within the grand-cycle may be about 1:1 to about 1:40. In some embodiments, the ratio of M:N is about 1:2 to about 1:38, about 1:5 to about 1:36, about 1:10 to about 1:34, about 1:15 to about 1:32, about 1:20 to about 1:30, or any range therebetween.

The ratio of M:N may be determined considering the type of the deposition inhibiting layer used, deposition conditions, and the like. When the ratio of M:N is too large (i.e., when M is excessively large), a material layer may not be formed or may be formed too slowly. When the ratio of M:N is too small (i.e., when N is excessively large), the selectivity of material layer formation may be reduced.

When the deposition inhibiting layer 120 does not remain on the sidewall 112, in operation S40, it is determined whether the next operation of forming a material layer is completed (see FIG. 1). When the material layer formation is completed, the material layer formation process is terminated.

Otherwise, when the material layer formation is still insufficient, one grand-cycle including M times of the first sub-cycle and N times of the second sub-cycle may be performed for a total of X times of the grand-cycle until the material layer formation is completed.

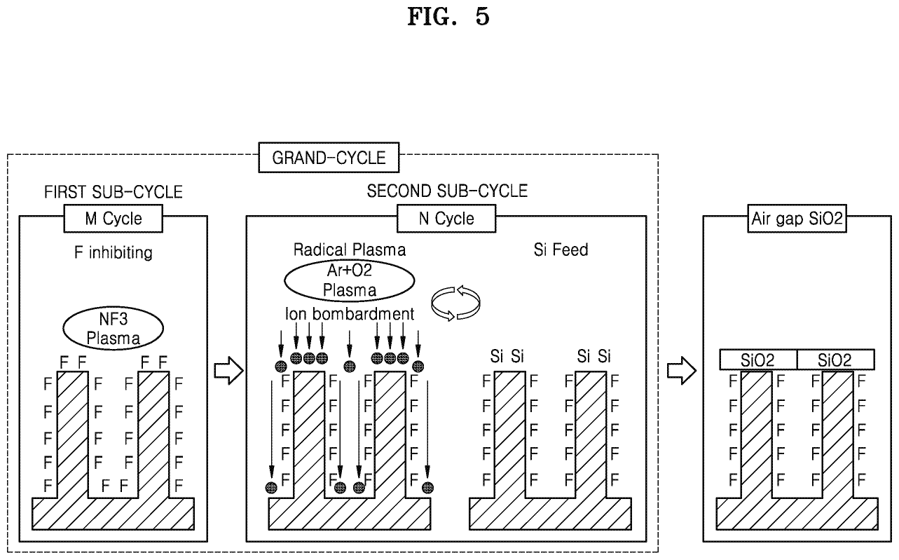

FIG. 5 is a schematic view illustrating a method of forming a material layer according to an embodiment.

Referring to FIG. 5, a grand-cycle includes a first sub-cycle and a second sub-cycle that follows the first sub-cycle.

In the first sub-cycle, a deposition inhibiting layer (here expressed as a fluorine (F) layer) is formed. In other words, by supplying NF3 as a deposition inhibitor and supplying plasma, the F layer may be uniformly formed on a substrate. The first sub-cycle may be performed once or a plurality of times.

The second sub-cycle includes supplying a source material, supplying a reactant, and supplying plasma. As the second sub-cycle is repeated, a deposition inhibiting material layer is partially removed by ion bombardment of oxygen ions by plasma. In other words, due to the ion bombardment of oxygen ions in a vertical direction, a deposition inhibiting layer on an upper surface and a lower surface in a direction perpendicular to an ion propagation direction is removed, and a deposition inhibiting layer on a sidewall generally remains. For example, the deposition inhibiting layer may be removed by the following reaction equation.

2F⁻+(1/2)O₂+(ionization energy)→2F⁻+O²⁺→OF₂(↑)

Thereafter, a source material is adsorbed on the upper surface and the lower surface compared to the sidewall, particularly on the upper surface, and the adsorbed source material reacts with a reactant to form a material layer (here SiO₂). This second sub-cycle may be repeated until the material layer has a desired thickness, shape, etc. in a range in which the deposition inhibiting layer remains on the sidewall.

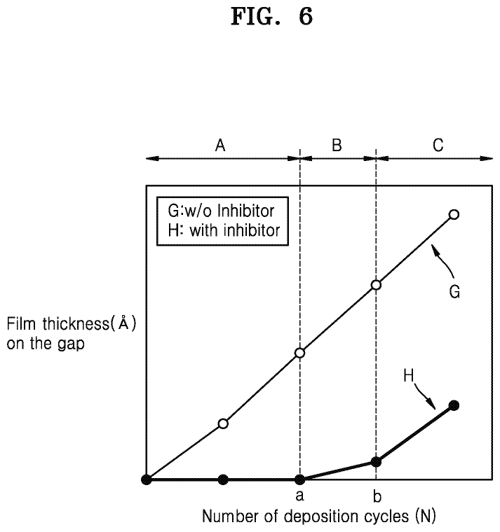

FIG. 6 is a graph for comparing film formation rates of a material layer in the absence of a deposition inhibiting layer (G) and in the presence of a deposition inhibiting layer (H).

Referring to FIG. 6, a horizontal axis of the graph denotes the number of deposition cycles and a vertical axis denotes the thickness of a film grown on a gap structure. When the deposition inhibiting layer is not present (G), it appears that a material layer is proportionally formed on the gap structure as the deposition cycle is repeated.

On the other hand, when the deposition inhibiting layer is present (H), a material layer is not formed on the gap structure due to the deposition inhibiting layer until the number of deposition cycles reaches a certain number (a) (section A). This step may be referred to as a non-recovery state in that a surface on which a deposition inhibiting layer is formed is present even though a deposition cycle is repeated, or an incubation period in that a material layer is not formed even when a deposition cycle is repeated.

In the case of the structure shown in FIG. 2B, the deposition inhibiting layer 120 on the upper surface 113 and the lower surface 111 is gradually removed. In this case, the deposition inhibiting layer 120 on the sidewall 112 may be removed relatively slowly or may be hardly removed.

Thereafter, as the deposition inhibiting layer is partially removed as the deposition cycle is repeated, the material layer grows partially, discontinuously, and slowly (section B). Accordingly, the gradient of the growth of the material layer is less than that in the case (G) where the deposition inhibiting layer is not present.

This step may be referred to as an insufficient recovery state in that a surface from which the deposition inhibiting layer has been removed is partially present as the deposition cycle is repeated, but is insufficiently recovered to the state before the deposition inhibiting layer is formed.

In the case of the structure shown in FIG. 2B, the deposition inhibiting layer 120 on the upper surface 113 and the lower surface 111 is sufficiently removed to form the material layer. Although the deposition inhibiting layer 120 on the sidewall 112 is thinner than the deposition inhibiting layer in the non-recovery state (section A in FIG. 6), it is still present, thereby enabling selective formation of a material layer between the sidewall 112 and the upper surface 113.

Thereafter, when the deposition cycle is performed a certain number of times (b) or more, the deposition inhibiting layer is all removed, so that there is no difference in the growth rate (i.e., the slope) of a material layer from the case where the deposition inhibiting layer is not present (G) (section C).

This step may be referred to as a sufficient recovery state in that the deposition inhibiting layer is sufficiently removed and sufficiently recovered to a state before the deposition inhibiting layer is formed.

In the case of the structure shown in FIG. 2B, because the growth rate of a material layer on the upper surface 113 is fast, the air gap AG is formed as shown in FIG. 2C, whereas a material layer may not be formed or only partially formed on the sidewall 112. When the deposition inhibiting layer 120 on the sidewall 112 is removed before the air gap AG is formed, a material layer may be formed on the sidewall 112 as well. However, the material layer formed on the sidewall 112 may have a relatively less thickness.

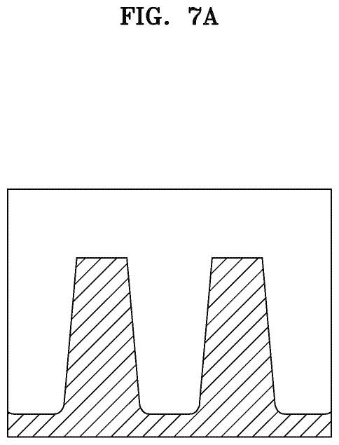

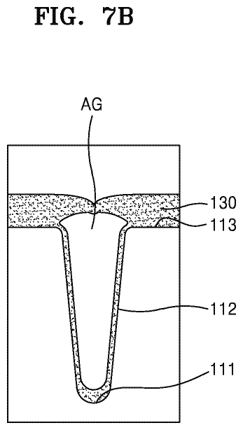

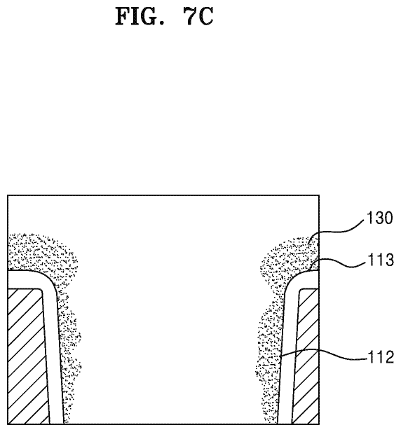

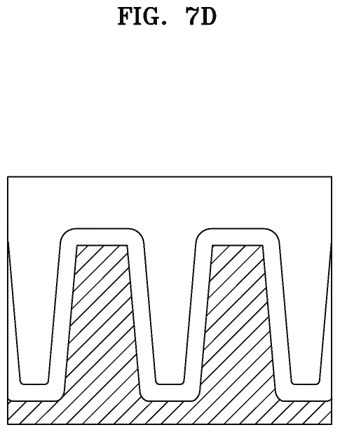

FIGS. 7A to 7D are images illustrating a profile of a SiO₂ film formed on a gap structure according to each step of FIG. 6.

The image of FIG. 7A corresponds to H of section A of FIG. 6, and a material layer is not formed due to a deposition inhibiting layer.

The image of FIG. 7B corresponds to H of section B of FIG. 6, and it can be seen that a deposition inhibiting layer remains on the sidewall 112, so that a material layer is hardly formed on the sidewall 112. A shape and a volume of the air gap AG are substantially respectively the same as an internal shape of the gap structure, that is, a shape and a volume of a gap space surrounded by sidewalls, a bottom surface, and an upper area of a gap.

The image of FIG. 7C shows a case in which an air gap is not formed. It is also observed that a material layer is discontinuously formed on the sidewall 112. This means that a deposition inhibiting layer is intermittently removed even on the sidewall 112, and a material layer is formed on the removed portion.

The images of FIGS. 7B and 7C both correspond to H of section B of the graph of FIG. 6, but the image of FIG. 7B is close to the side a and the image of FIG. 7C is close to the side b.

FIG. 7D shows that a deposition inhibiting layer is sufficiently removed even on a sidewall so that a material layer is also formed on the sidewall, and corresponds to H of section C of the graph of FIG. 6. As shown in FIG. 7D, it is observed that a uniform material layer is also formed on the sidewall.

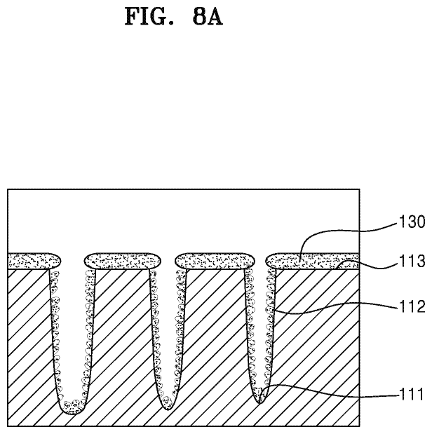

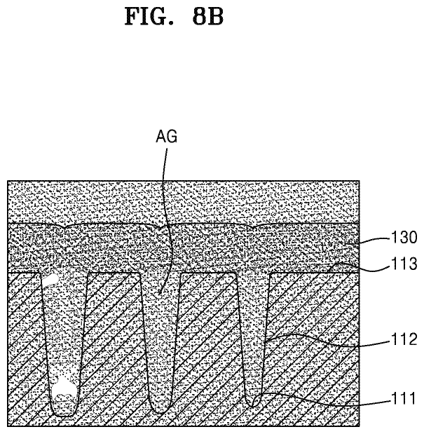

FIGS. 8A and 8B are images illustrating the formation of a SiO₂ material layer according to the number of deposition cycles in section B of FIG. 6.

FIG. 8A is a case in which the number of deposition cycles in section B is close to cycle a. Referring to FIG. 8A, it is observed that the formation of the SiO₂ material layer is suppressed on the sidewall 112 of a gap and the SiO₂ material layer is selectively deposited on the upper surface 113 and the lower surface 111 of a gap structure.

FIG. 8B is a case in which the number of deposition cycles in section B is close to cycle b. It is observed that a SiO₂ material layer on the upper surface 113 grows thicker so that adjacent SiO₂ material layers are connected to each other and the air gap AG is formed, and a SiO₂ material layer is gradually formed while the SiO₂ material layer is discontinuously formed on the side surface 112 of the gap.

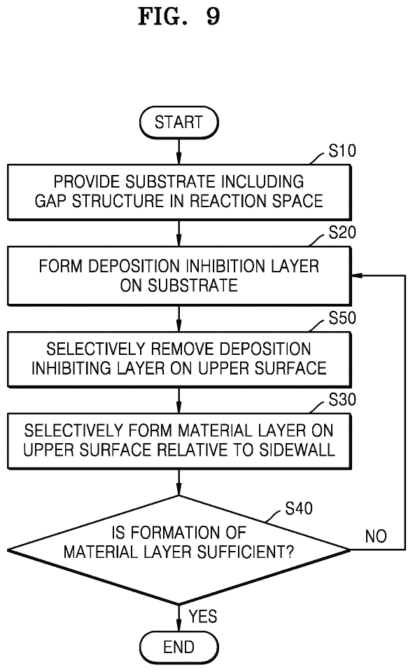

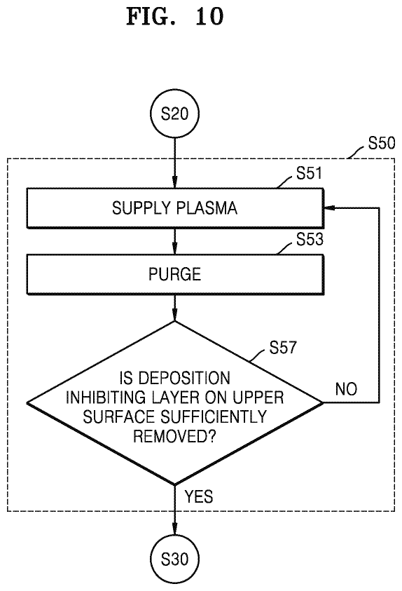

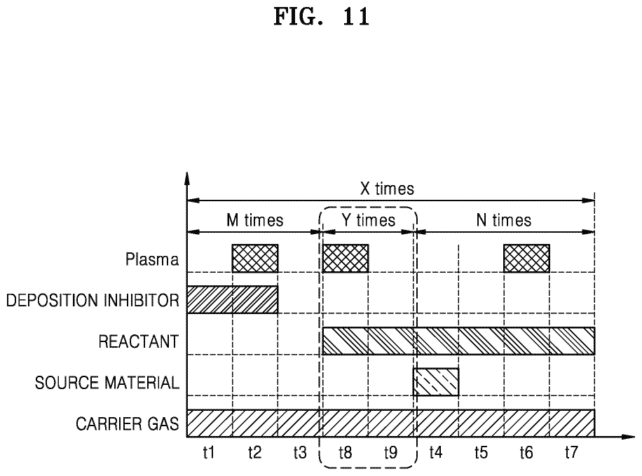

FIG. 9 is a flowchart illustrating a method of forming a material layer according to another embodiment. FIG. 10 is a detailed flowchart illustrating a method of selectively removing a deposition inhibiting layer on an upper surface of FIG. 9. FIG. 11 is a timing diagram illustrating the method of FIG. 10.

The method of forming a material layer according to another embodiment of FIG. 9 is substantially the same as the method of forming a material layer described with reference to FIG. 1, except that it further includes selectively removing a deposition inhibiting layer on an upper surface. Accordingly, the following description will focus on these differences.

Referring to FIGS. 9 to 11, the method of forming a material layer in the present embodiment includes operation S50 of selectively removing a deposition inhibiting layer from an upper surface compared to a sidewall between operation S20 of forming a deposition inhibiting layer on a substrate and operation S30 of selectively forming a material layer on an upper surface compared to a sidewall.

Operation S50 of selectively removing the deposition inhibiting layer on the upper surface may include, as shown in FIG. 11, an eighth period (t8) and a ninth period (t9) between the third period (t3) and the fourth period (t4). Terms such as ‘third’, ‘fourth’, ‘eighth’, ‘ninth’ are for simple identification and do not mean a specific order as mentioned above.

Eighth Period (t8)

The eighth period (t8) may be performed after operation S20 of forming a deposition inhibiting layer on a substrate. In operation S51, at the eighth period (t8), a reactant may be activated by supplying plasma while continuously supplying the reactant to a reaction space in which the substrate is mounted. That is, in operation S51, plasma may be applied while continuously supplying the reactant to the substrate during the eighth period (t8).

By supplying plasma while supplying the reactant, the reactant may be activated and thereby the reactant may be ionized. Plasma may be generated by supplying RF power to the reaction space.

The applying of plasma to the reactant may cause the ionized reactant to collide substantially perpendicularly onto the substrate. The ionized reactant is charged, so the ionized reactant may move with directionality, and the resulting ion bombardment may collide and react with the deposition inhibiting layer on the substrate, in particular, on the upper surface 113 to remove the deposition inhibiting layer from the upper surface 113. In addition, by the ion bombardment, the deposition inhibiting layer 120 on the sidewall 112 is removed relatively slowly compared to the upper surface 113. In other words, by the ion bombardment, the deposition inhibiting layer on the upper surface 113 may be selectively removed compared to the deposition inhibiting layer on the sidewall 112.

The reactant at the eighth period (t8) may be the same as or different from the reactant at the fourth period (t4) and/or the sixth period (6). For example, in the fourth period (t4) and/or the sixth period (t6), a reactant (first reactant) capable of serving as a source of nitrogen is used, and in the eighth period (t8), a reactant (second reactant) capable of serving as a source of oxygen may be used. Alternatively, in the fourth period (t4) and/or the sixth period (t6), a reactant capable of acting as a source of oxygen is used, and in the eighth period (t8), a reactant capable of serving as a source of nitrogen may be used.

A time for applying the plasma (i.e., the duration of the eighth period (t8)) may be about 0.1 second to about 1 second. At this time, in order to apply the plasma, high-frequency RF power having a frequency of about 13.56 MHz may be supplied to the reaction space at power of about 100 W to about 400 W. In some embodiments, unlike in the first sub-cycle, low-frequency RF power having a frequency of about 400 kHz may not be supplied.

The reactant may be carried by a carrier gas. The carrier gas is an inert gas, and Ar, He, N₂, Ne, etc. may be used, but is not limited thereto. A flow rate of the carrier gas may be appropriately selected considering factors such as a flow rate of the reactant, a vapor pressure of a reactant to be transported, and the temperature. For example, about 1000 sccm to about 3000 sccm of Ar or N₂ gas may be supplied as a carrier gas.

In addition, in order to prevent a process gas, such as a source material, a deposition inhibitor, and a reactant, from penetrating into a lower space of a susceptor supporting a substrate in a reaction space, a filling gas may be further provided to the lower space of the susceptor. The filling gas may be, for example, N₂, and may be provided at a flow rate of about 50 sccm to about 200 sccm.

In some embodiments, a reactant may be continuously supplied while the plasma application is performed. A supply rate of the reactant may be about 500 sccm to about 2000 sccm.

Ninth Period (t9)

Thereafter, in operation S53, the application of the plasma may be stopped and the reaction space may be purged.

In some embodiments, the purge operation may be performed by supplying a carrier gas to the reaction space during the ninth period (t9). The carrier gas is an inert gas, and Ar, He, N₂, Ne, etc. may be used, but is not limited thereto. A flow rate of the carrier gas may be, for example, about 200 sccm to about 3000 sccm of Ar or N₂ gas.

In some embodiments, the reactant may be continuously supplied while the purge operation is performed. The supply rate of the reactant may be the same as that of the eighth period (t8).

The time the purge operation is performed (i.e., the duration of the ninth period (t9)) may be about 0.1 second to about 1 second.

The above operations S51 and S53 may form an ion bombardment sub-cycle.

Thereafter, in operation S57, it is determined whether the deposition inhibiting layer 120 on the upper surface 113 has been sufficiently removed. When the deposition inhibiting layer 120 on the upper surface 113 is not sufficiently removed, the ion bombardment sub-cycle may be repeated. In some embodiments, the ion bombardment sub-cycle may be performed multiple times, such as 2 to 10 times, within the one grand-cycle.

Table 1 shows process conditions according to an embodiment. The example of Table 1 may form an air gap structure while depositing a SiO₂ film on a gap structure.

TABLE 1

| | | Formation of | |
|---|---|---|---|
| | | deposition | |
| Process parameters | | inhibiting layer | Deposition step |
| Gas supply | Source carrier Ar | 1,000 to 3,000 | 1,000 to 3,000 |
| rate (sccm) | Reactant (O2) | 0 | 500 to 2,000 |
| | Deposition inhibitor (NF₃) | 5 to 300 | 0 |
| | Purge Ar | 1,000 to 6,000 | 200 to 3,000 |
| | Bottom N₂ (charge gas) | 50 to 200 | 50 to 1,000 |
| Processing time | Deposition inhibitor supply | 0.1 to 1.0 | 0 |
| per step (sec) | (RF-on) | | |
| | Deposition inhibitor purge | 0.1 to 1.0 | 0 |
| | Source supply | 0 | 0.1 to 1.0 |
| | Source purge | 0 | 0.1 to 1.0 |
| | Reactant supply (RF-on) | 0 | 0.1 to 1.0 |
| | Reactant purge | 0 | 0.1 to 1.0 |
| RF power by | High frequency (13.56 MHz) | 100 W to 400 W | 100 W to 400 W |
| frequency (W) | Low frequency (400 kHz) | 50 W to 150 W | 0 |

| | | |
|---|---|---|
| Cycle ratio (M:N) | 1 | 10 to 100 |

| | |
|---|---|
| Process pressure (Torr) | 2 Torr to 5 Torr |
| Process temperature (° C.) | Room temperature to 600° C. |

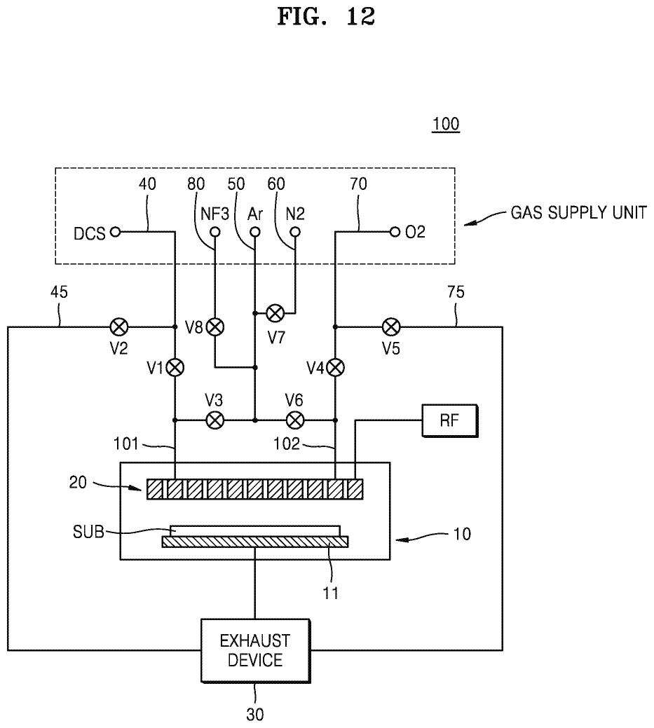

FIG. 12 schematically illustrates a substrate processing apparatus 100 to which a method of forming a material layer according to embodiments may be applied.

Referring to FIG. 12, the substrate processing apparatus 100 may be implemented in a manner of supplying gas in a vertical direction toward a substrate using a gas injection device. For example, the substrate processing apparatus 100 of FIG. 12 may be a plasma enhanced atomic layer deposition (PEALD) apparatus for forming a silicon oxide film or a silicon nitride film. Hereinafter, on the premise that dichlorosilane (DCS, Si₂H₂Cl₂) is used as a source material of silicon, oxygen (O₂) is used as a reactant, and NF3 is used as a deposition inhibitor, a substrate processing apparatus according to embodiments will be described.

An atomic layer deposition apparatus may include a reaction chamber 10, a gas injection device 20, an exhaust device 30, a DCS supply pipe 40, an Ar supply pipe 50, a N₂ supply pipe 60, an O₂ supply pipe 70, a NF₃ supply pipe 80, a DCS bypass line 45, an O₂ bypass line 75, a first supply pipe 101, and a second supply pipe 102. In addition, the atomic layer deposition apparatus may further include valves V1 to V8 for controlling the gas flow in tubes. Functions of the first valves V1 to V8 are as follows.
The first valve V1: Control of connection between the DCS supply pipe 40 and the first supply pipe 101
The second valve V2: Control of connection between the DCS supply pipe 40 and the DCS bypass line 45
The third valve V3: Control of connection between the Ar supply pipe 50 and the first supply pipe 101
The fourth valve V4: Control of connection between the O2 supply pipe 70 and the second supply pipe 102
The fifth valve V5: Control of connection between the O2 supply pipe 70 and the O2 bypass line 75
The sixth valve V6: Control of connection between the Ar supply pipe 50 and the first supply pipe 102
The seventh valve V7: Control of connection between the Ar supply pipe 50 and the N2 supply pipe 60
The eighth valve V8: Control of connection between the Ar supply pipe 50 and the NF3 supply pipe 80

The reaction chamber 10 is a space for depositing a silicon oxide thin film on a semiconductor substrate (not shown), and may be an enclosed space. To this end, the reaction chamber 10 may be isolated from the outside of a reactor using a sealing device such as a seal gas and/or an O-ring, and may be maintained at a pressure below atmospheric pressure. A substrate support device or a susceptor 11 on which a semiconductor substrate SUB is placed may be arranged in the reaction chamber 10, and a gate valve (not shown) for allowing the semiconductor substrate SUB to enter and exit may be installed on a side surface of the reaction chamber 10. In this case, the gate valve may be opened only when the semiconductor substrate SUB enters and exits and maintains a closed state during the process.

The gas injection device 20 may be configured to uniformly supply DCS, O₂, NF₃, Ar, and N₂ supplied through the first supply pipe 101 and the second supply pipe 102 onto the semiconductor substrate SUB. For example, the gas injection device 20 may be a shower head. In an optional embodiment, the gas injection device 20 may be connected to an RF plasma generator, and accordingly, a plasma atomic layer deposition process may be performed. In another embodiment, the gas injection device 20 may act as a plasma electrode.

A source material and a reactant passing through the reaction chamber 10 may be exhausted through the exhaust device 30. The exhaust device 30 may include at least one exhaust pipe (not shown) connected to the outside.

The substrate processing apparatus 100 may further include bypass lines. For example, as in the present embodiment, the substrate processing apparatus 100 may include a DCS bypass line 45 and an O₂ bypass line 75. In this case, NF₃, DCS, and O₂ are respectively supplied to the reaction chamber 10 in a timely manner to proceed with an atomic layer deposition process, and each valve may be operated in accordance with the timing diagrams of FIGS. 4 and 11.

By using a method of forming a material layer of the disclosure, not only may an air gap structure be easily formed on a gap structure, but also the shape and size of an air gap may be controlled by adjusting a repetition ratio of supplying a deposition inhibitor and forming a material layer.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. An air gap forming method of forming an air gap in a gap structure having an upper surface, a lower surface, and a sidewall connecting the upper and lower surfaces, the air gap forming method comprising:
repeatedly performing a selective deposition cycle, wherein the selective deposition cycle comprises:
supplying a deposition inhibitor onto a substrate including the gap structure; and
selectively forming a material layer on the upper surface compared to the sidewall.

2. The air gap forming method of claim 1, wherein
the supplying of the deposition inhibitor comprises performing a first sub-cycle once or a plurality of times, wherein the first sub-cycle comprises:
supplying an ionized deposition inhibitor onto the substrate; and
supplying a purge gas.

3. The air gap forming method of claim 2, wherein
the selectively forming of the material layer comprises performing a second sub-cycle once or a plurality of times, wherein the second sub-cycle comprises:
supplying a source material;
purging an excess of a source material;
supplying an ionized first reactant; and
purging an excess of a first reactant.

4. The air gap forming method of claim 3, further comprising:
performing one or a plurality of ion bombardment sub-cycles between the supplying of the deposition inhibitor and the selectively forming of the material layer,
wherein the ion bombardment sub-cycle comprises:
supplying a second reactant onto the substrate;
supplying plasma to a reaction space by ionizing and impinging the second reactant substantially perpendicularly onto the substrate; and
purging an excess of a second reactant.

5. The air gap forming method of claim 2, wherein
a ratio of the number of times of performing the first sub-cycle to the number of times of performing the second sub-cycle is 1:1 to 1:40.

6. The air gap forming method of claim 2, wherein
a ratio of the number of times of performing the first sub-cycle to and the number of times of performing the second sub-cycle is 1:20 to 1:30.

7. The air gap forming method of claim 2, wherein
the deposition inhibitor is a halogen-containing compound.

8. The air gap forming method of claim 7, wherein
the deposition inhibitor is at least one selected from a group consisting of F₂, SF₆, CF₄, C₂F₆, CHF₃, CH₂F₂, ClF₃, NF₃, C₃F₈, C₄F₈, HF, SiF₄, Cl₂, HCl, BCl₃, CCl₄, SiCl₄, SiHCl₃, SiH₂Cl₂, Si₂Cl₆, CHCl₃, CH₂Cl₂, CH₃Cl, PCl₃, PCl₅, POCl₃, NCl₃, S₂Cl₂, SOCl₂, SO₂Cl₂, COCl₂, and HBr.

9. The air gap forming method of claim 7, wherein,
by the supplying of the deposition inhibitor, a layer of a halogen element is uniformly formed on the upper surface, the lower surface, and the sidewall of the gap structure.

10. The air gap forming method of claim 9, wherein,
as the second sub-cycle is repeated while the selectively forming of the material layer is performed, the layer of the halogen element on the upper surface is removed faster than the layer of the halogen element on the sidewall is removed.

11. A selective deposition method of selectively depositing a material layer on a gap structure having an upper surface, a lower surface, and a sidewall connecting the upper surface and the lower surface, the selective deposition method comprising: repeating selective deposition cycles within a reaction chamber,
wherein the selective deposition cycle comprises:
uniformly forming a deposition inhibiting layer on the upper surface, the lower surface, and the sidewall;
selectively removing the deposition inhibiting layer from the upper surface relative to the sidewall; and
selectively depositing the material layer on the upper surface while the deposition inhibiting layer remains on the sidewall.

12. The selective deposition method of claim 11, wherein
the selectively removing of the deposition inhibiting layer from the upper surface and the selectively depositing of the material layer on the upper surface are performed simultaneously.

13. The selective deposition method of claim 11, wherein
the uniformly forming of the deposition inhibitory layer comprises:
ionizing a deposition inhibitor; and
supplying the ionized deposition inhibitor onto the substrate.

14. The selective deposition method of claim 13, wherein
the selectively depositing of the material layer on the upper surface comprises:
supplying a source material onto the substrate; and
supplying an ionized first reactant on the substrate after the supplying of the source material.

15. The selective deposition method of claim 14, wherein
the selectively removing of the deposition inhibiting layer from the upper surface is performed prior to the selectively depositing of the material layer on the upper surface,
wherein the selectively removing of the deposition inhibiting layer from the upper surface comprises: repeating one or more ion bombardment cycles including:
supplying a second reactant onto the substrate;
supplying plasma to a reaction chamber by ionizing and impinging the second reactant substantially perpendicularly onto the substrate; and
purging an excess of the second reactant.

16. The selective deposition method of claim 15, wherein the first reactant material and the second reactant material each independently includes at least one selected from a group consisting of O₂, O₃, plasma O₂, plasma O₃, water vapor, plasma H₂O, NO, plasma NO, N₂O, plasma N₂O, NO₂, plasma NO₂, hydrogen peroxide, CO, plasma CO, CO₂, plasma CO₂, nitrogen (N₂), ammonia (NH₃)), hydrazine (N₂H₄), diazene (N₂H₂), plasma N₂, plasma NH₃, plasma H₂, and NF₃.

17. The selective deposition method of claim 15, wherein
the material layer is silicon oxide or silicon nitride, and the source material is at least one selected from a group consisting of silane (SiH₄), disilane (Si₂H₆), trisilane (Si₃H₈), monochlorosilane (SiClH₃), dichlorosilane (SiCl₂H₂, DCS), trichlorosilane (SiCl₃H), tetrachlorosilane (SiCl₄), hexachlorodisilane (Si₂Cl₆, HCD), diiodosilane (SiH₂I₂, DIS), triiodosilane (Sil₃H, TIS), diethylsilane (Et₂SiH₂), tetraethyl orthosilicate (Si(OCH₂CH₃)₄, TEOS), diisopropylaminosilane (H₃Si(N(i-Pr)₂)), bis(tertiary-butylamino)silane ((C₄H₉(H)N)₂SiH₂), tetrakis(ethylamino)silane (Si(NHEt)₄), tetrakis(dimethylamino)silane (Si(NMe₂)₄), tetrakis(ethylmethylamino)silane (Si(NEtMe)₄), tetrakis(diethylamino)silane (Si(NEt₂))₄), tris(dimethylamino)silane (HSi(NMe₂)₃), tris(ethylmethylamino)silane (HSi(NEtMe)₃), tris(diethylamino)silane (HSi(NEt₂)₃), tris(dimethylhydrazino)silane (HSi(N(H)NMe₂)₃), bis(diethylamino)silane (H₂Si(NEt₂)₂), bis(diisopropylamino)silane (H₂Si(N(i-Pr)₂)₂), tris(isopropylamino)silane (HSi(N(i-Pr)₂)₃), (diisopropylamino)silane (H₃SiN(i-Pr)₂), trisilylamine ((SiH₃)₃N, TSA), disiloxane (DSO), disilylmethylamine ((SiH₃)₂NMe, DSMA), disilylethylamine ((SiH₃)₂NEt, DSEA), disilylisopropylamine ((SiH₃)₂N(i-Pr), DSIPA), disilyl-tert-butylamine ((SiH₃)₂N(tBu), DSTBA), diethylsilylamine (SiH₃NEt₂, DESA), di-tert-butylsilylamine (SiH₃N(tBu)₂, DTBSA), bis(diethylamino)silane (SiH₂(NEt₂)₂, BDEAS), bis(dimethylamino)silane (SiH₂(NMe₂)₂, BDMAS), bis(ethylmethylamino)silane (SiH₂[N(Et)(Me)]₂, BEMAS), bis(tert-butylamino)silane (SiH₂(NHtBu)₂, BTBAS), diisopropylsilylamine (SiH₃N(i-Pr)₂, DIPSA), hexakis(ethylamino)disilane (Si₂(NHEt)₆), and bis(trimethylsilylamino)silane (SiH₂(NHSiMe₃)₂, BITS).

18. The selective deposition method of claim 11, wherein,
in the uniformly forming of the deposition inhibiting layer, high-frequency RF power and low-frequency RF power are simultaneously supplied to the reaction chamber.

19. The selective deposition method of claim 11, wherein,
in the selectively removing of the deposition inhibiting layer from the upper surface relative to the sidewall, high-frequency RF power is supplied to the reaction chamber.
